(19) United States
(12) Patent Application Publication
(10) Pub. No.: US 2012/0243325 A1
(43) Pub. Date: Sep. 27, 2012

(54) SEMICONDUCTOR MEMORY DEVICE

(75) Inventor: Tsuneaki Fuse, Setagaya-ku (JP)

(73) Assignee: KABUSHIKI KAISHA TOSHIBA, Tokyo (JP)

(21) Appl. No.: 13/206,686

(22) Filed: Aug. 10, 2011

(30) Foreign Application Priority Data
Mar. 24, 2011 (JP) 2011-65182

(51) Int. Cl. G11C 16/28; G11C 16/04

(52) U.S. Cl. 365/185.21; 365/185.18

(57) ABSTRACT

A semiconductor memory device according to one embodiment includes: a memory cell array including electrically-rewritable memory cells; bit lines each connected to one end of the memory cells and charged in response to a certain operation; and a voltage generating circuit configured to control a charging operation on the bit lines. The voltage generating circuit includes: a regulator configured to regulate voltages of a first node and a second node; and a clamp transistor connected at its one end to a bit line and connected at its gate to the first node. The regulator includes a first transistor diode-connected between the first node and the second node to form a current path therebetween and configured to let flow therethrough an output current variable according to an output signal of the regulator. The first transistor and the clamp transistor have approximately equal threshold voltages.

### CROSS REFERENCE TO RELATED APPLICATIONS

This application is based on and claims the benefit of priority from prior Japanese Patent Application No. 2011-65182, filed on Mar. 24, 2011, the entire contents of which are incorporated herein by reference.

### BACKGROUND

1. Field

Embodiments described herein relate generally to a semiconductor memory device.

2. Description of the Related Art

NAND type flash memories have been known as electrically-rewritable semiconductor memory devices that are capable of a high degree of integration. In a NAND type flash memory, a NAND cell unit is configured by a plurality of memory cells that are connected in series such that a source diffusion layer of one memory cell is shared as a drain diffusion layer of its adjoining memory cell. Both ends of the NAND cell unit are connected to a bit line and a source line respectively through select gate transistors. Such a configuration of the NAND cell unit realizes a smaller unit cell area and a larger memory capacity than those realized in a NOR type memory.

A memory cell of a NAND type flash memory includes a charge accumulation layer (a floating gate electrode) formed above a semiconductor substrate via a tunnel insulating film, and a control gate electrode stacked above the charge accumulation layer via an inter-gate insulating film, and stores data in a nonvolatile manner according to a charge accumulation state of the floating gate electrode. For example, a memory cell of a NAND type flash memory executes binary data storage in which a high threshold voltage state with charges injected in the floating gate electrode is represented by data “0” and a low threshold voltage state with charges discharged from the floating gate electrode is represented by data “1”. Recent memory cells also store multi-value data such as four-value data, eight-value data, and so on, by subdividing the threshold voltage distributions to be written.

In a data reading, a reading voltage is supplied to a selected word line connected to a selected memory cell in the NAND cell unit. Meanwhile, a reading pass voltage is applied to unselected word lines connected to unselected memory cells. Then, the current or voltage of the selected bit line connected to the NAND cell unit including the selected memory cell is compared with the current or voltage of a reference bit line by a sense amplifier to determine whether the data retained in the memory cell is data “1” or data “0”. According to this scheme, it is necessary to pre-charge the selected bit line to be read and the reference bit line up to a certain voltage before operating the sense amplifier.

When the current or voltage of the selected bit line is high, the sense amplifier can operate with a relatively large margin set between the selected bit line and the reference bit line and hence can execute a reading operation accurately. However, if reduction in the memory cell size accompanying the increasing integration of semiconductor memory devices causes the current or voltage of the bit lines to become low, the operation margin of the sense amplifier becomes small. When the operation margin of the sense amplifier is small, the sense amplifier might cause erroneous reading due to dispersions of the manufacturing process, the temperature, the power supply voltage, and so on. Therefore, it is necessary to control the pre-charge voltage of the selected bit line more accurately. That is, it is necessary to maintain the pre-charge voltage to an optimum value even when there occur dispersions of the manufacturing process, the temperature, the power supply voltage, and so on.

### BRIEF DESCRIPTION OF THE DRAWINGS

FIG. 1 is a circuit diagram showing the configuration of a memory cell array of a semiconductor memory device according to an embodiment.

FIG. 2 is a diagram showing an example of data storage in a semiconductor memory device according to an embodiment.

FIG. 3 is a circuit diagram showing a voltage generating circuit of a semiconductor memory device according to a comparative example.

FIG. 4 is a circuit diagram showing a voltage generating circuit of a semiconductor memory device according to a first embodiment.

FIG. 5 is a circuit diagram showing a voltage generating circuit of a semiconductor memory device according to a second embodiment.

FIG. 6 is a circuit diagram showing a voltage generating circuit of a semiconductor memory device according to a third embodiment.

FIG. 7 is a circuit diagram showing a voltage generating circuit of a semiconductor memory device according to a fourth embodiment.

FIG. 8 is a circuit diagram showing a voltage generating circuit of a semiconductor memory device according to another example.

### DETAILED DESCRIPTION

A semiconductor memory device according to one embodiment includes: a memory cell array including electrically-rewritable memory cells; bit lines each connected to one end of the memory cells and charged in response to a certain operation; and a voltage generating circuit configured to control a charging operation on the bit lines. The voltage generating circuit includes: a regulator configured to regulate voltages of a first node and a second node; and a clamp transistor connected at its one end to a bit line and connected at its gate to the first node. The regulator includes a first transistor diode-connected between the first node and the second node to form a current path therebetween and configured to let flow therethrough an output current variable according to an output signal of the regulator. The first transistor and the clamp transistor have approximately equal threshold voltages.

A semiconductor memory device according to the embodiments will be explained with reference to the drawings.

### First Embodiment

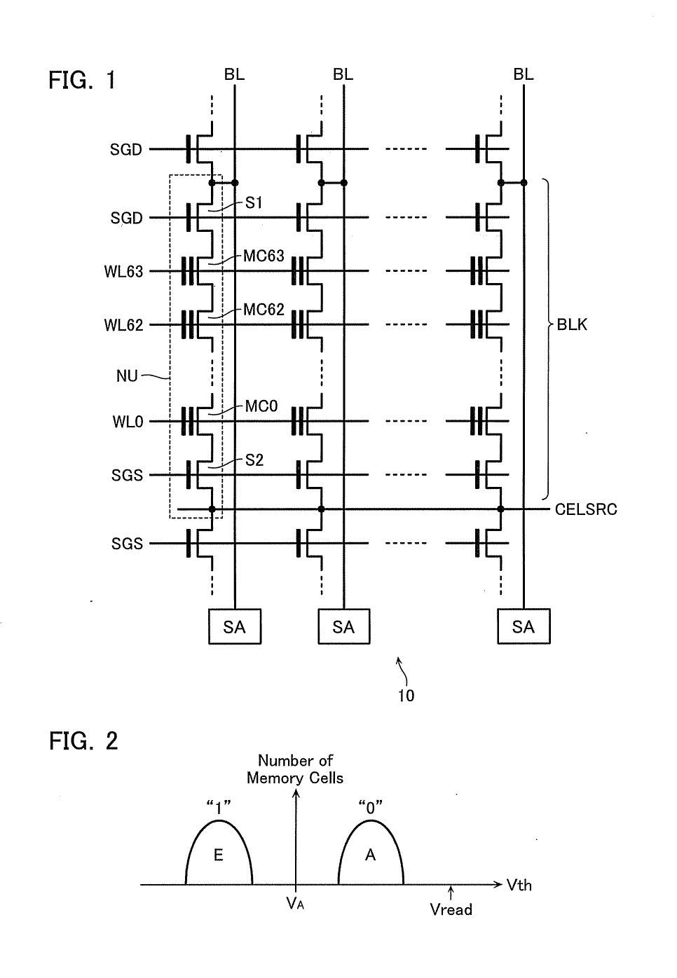

FIG. 1 is a circuit diagram showing a memory cell array of a semiconductor memory device according to a first embodiment.

As shown in FIG. 1, a memory cell array 10 is configured by NAND cell units NU arranged in a matrix. Each NAND cell unit NU includes a plurality of (64 in the example of FIG. 1) electrically-rewritable memory cells MC0 to MC63 connected in series, and select gate transistors S1 and S2 for connecting both ends of the memory cells to a bit line EL and a common source line CELSRC respectively. For example, each memory cell MC may have a stacked-gates configuration having a gate insulating film, a floating gate electrode, an inter-gate insulating film, and a control gate electrode stacked above a p-type well formed in a semiconductor substrate.

The control gates of the memory cells MC in a NAND cell unit NU are connected to different word lines WL0 to WL63 respectively. The gates of the select gate transistors S1 and S2 are connected to select gate lines SGD and SGS respectively. An aggregate of NAND cell units NU sharing one word line constitutes a block to serve as a data erasing unit. As shown in FIG. 1, a plurality of blocks ELK are arranged in the direction in which the bit lines BL extend. Each bit line BL is connected to a sense amplifier SA and a voltage generating circuit to be described later. Memory cells MC connected commonly to one word line WL constitute one page.

[Data Storage]

Next, an outline of a data storage scheme of the semiconductor memory device will be explained with reference to FIG. 2. FIG. 2 shows a relationship between data to be stored in the memory cells MC and threshold voltage distributions.

FIG. 2 shows a relationship between data (“1” and “0”) and threshold voltage distribution, regarding the case when each memory cell MC stores one bit (binary data). A threshold voltage distribution E of a memory cell MC after block-base erasing is assigned data “1”. A threshold voltage distribution A is assigned data “0”. In FIG. 2, a reading voltage VA is a voltage to be applied to the control gate of a selected memory cell MC (or to a selected word line WL) that is selected in a data reading. A reading pass voltage Vread is a voltage applied to the control gates of unselected memory cells MC (or to unselected word lines WL) in a data reading, thereby making the unselected memory cells MC conductive regardless of the data stored therein. The present invention is not limited to embodiments in which one memory cell MC stores binary data, but may be applied to schemes for storing four-value data and eight-value data.

[Operation of Semiconductor Memory Device]

A writing operation and an erasing operation are operations of controlling a certain voltage to be applied between the channel and gate electrode of a memory cell MC to inject charges into the floating gate electrode or discharge charges from the floating gate electrode. This changes the threshold voltage of the memory cell MC. In a data reading operation, a reading voltage is supplied to a word line WL (a selected word line) connected to a selected memory cell MC in a NAND cell unit NU. Meanwhile, a reading pass voltage Vread is applied to word lines WL (unselected word lines) connected to unselected memory cells MC. At this time, the current or voltage of the bit line BL connected to the NAND cell unit NU including the selected memory cell MC is compared with the current or voltage of a reference bit line provided in a sense amplifier SA to be described later to determine whether the data retained in the memory cell MC is data “1” or data “0”.

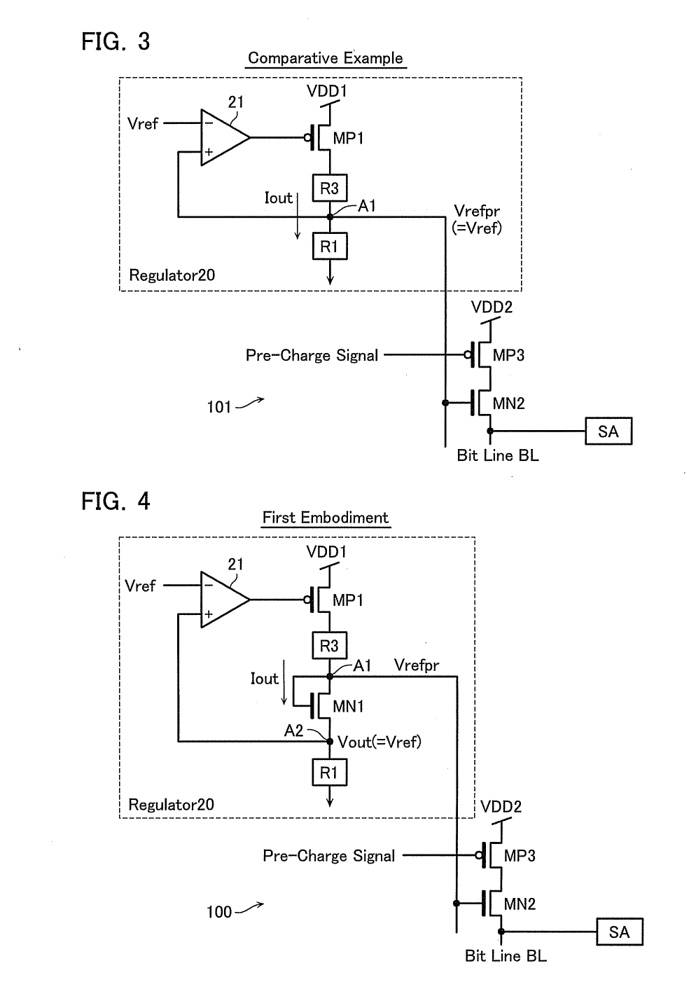

According to this scheme, before operating the sense amplifier SA, it is necessary to pre-charge the bit line BL to be read and the reference bit line provided in the sense amplifier SA to be described later up to a certain voltage. In the following part of the first embodiment, a voltage generating circuit for pre-charging the bit line BL up to a certain voltage will be explained. First, a voltage generating circuit 101 according to a comparative example will be explained with reference to FIG. 3 and then a voltage generating circuit 100 according to the first embodiment will be explained.

[Voltage Generating Circuit according to Comparative Example]

FIG. 3 is a circuit diagram showing a voltage generating circuit 101 according to a comparative example. The voltage generating circuit 101 includes: a regulator 20 configured to control the voltage value of an output voltage Vrefpr to a constant value; a PMOS transistor MP3 (a switch transistor); and an NMOS transistor MN2 (a clamp transistor). FIG. 3 also shows a sense amplifier SA connected to the bit line BL and used for a reading operation.

The regulator 20 includes a differential amplifier 21, a PMOS transistor MP1, and resistors R1 and R3. An inverting input terminal of the differential amplifier 21 is applied with a reference voltage Vref and a non-inverting input terminal thereof is connected to a node A1. An output terminal of the differential amplifier 21 is connected to the gate of a p-channel-type transistor MP1. The transistor MP1 and the resistor R3 are connected in series between a power supply VDD1 and the node A1. The node A1 is grounded through the resistor R1. The regulator 20 is configured to compare the voltage of the node A1 with the reference voltage Vref to equalize the value of the output voltage Vrefpr to be output from the node A1 with the reference voltage Vref. The value of the voltage Vrefpr (=Vref) of the node A1 is a product (Iout×R1) between a current Iout flowing through the node A1 and the resistance value of the resistor R1.

The p-channel-type transistor MP3 and the n-channel-type transistor MN2 are connected in series between a power supply VDD2 and the bit line BL. The transistor MP3 is controlled between a conductive state and a non-conductive state based on a pre-charging signal input to its gate. The output voltage Vrefpr of the regulator 20 is applied to the gate of the transistor MN2.

When pre-charging the bit line BL by using the voltage generating circuit 101, the transistor MP3 becomes conductive based on a pre-charging signal. The transistor MN2 becomes conductive based on the output voltage Vrefpr of the regulator 20. At this time, the bit line BL is clamped by the transistor MN2 to a voltage (Vrefpr−Vth) that is lower than the output voltage Vrefpr of the regulator 20 by a threshold voltage Vth of the transistor MN2.

However, in the voltage generating circuit 101 according to the comparative example, the threshold voltage Vth of the transistor MN2 (clamp transistor) varies due to any dispersions in the manufacturing process of the transistor MN2, temperature characteristics, and so on, which causes a problem that the level of the pre-charge voltage to which the bit line BL is clamped also varies.

[Voltage Generating Circuit according to First Embodiment]

In view of this problem, the voltage generating circuit 100 according to the first embodiment employs the configuration to be described below. The voltage generating circuit 100 according to the present embodiment will now be explained with reference to FIG. 4. In FIG. 4, any components that are configured the same as in the comparative example will be denoted by the same reference numerals and redundant explanation about such components will not be given. The voltage generating circuit 100 according to the first embodiment is different from the voltage generating circuit 101 according to the comparative example in that an NMOS transistor MN1 is provided in the regulator 20.

The voltage generating circuit 100 according to the first embodiment includes a node A1 and a node A2 to divide a node for outputting an output voltage Vrefpr (=node A1) from a node to be compared with the reference voltage Vref (=node A2). The regulator 20 is configured to compare a voltage Vout of the node A2 with the reference voltage Vref to equalize the value of the voltage Vout of the node A2 with the reference voltage Vref. A transistor MN1 is diode-connected between the node A1 and the node A2. The transistor MN1 has an approximately equal characteristic to the transistor MN2 (a clamp transistor). In this case, the threshold voltages Vth of the transistors MN1 and MN2 also become approximately equal. Likewise, when the threshold voltages Vth of the transistors MN1 and MN2 vary, they vary to approximately equal values.

When pre-charging the bit line BL by using the voltage generating circuit 100, the regulator 20 operates to equalize the voltage Vout of the node A2 with the reference voltage Vref. Here, the output voltage Vrefpr of the node A1 of the regulator 20 becomes a voltage (Vref+Vth) that is higher than the reference voltage Vref by the threshold voltage Vth of the diode-connected transistor MN1. The transistor MN2 connected to the bit line BL becomes conductive based on this output voltage Vrefpr (=Vref+Vth). In this case, the bit line EL is clamped to the voltage Vref lower than the output voltage Vrefpr (=Vref+Vth) of the regulator 20 by the threshold voltage Vth of the transistor MN2.

[Advantage]

The reference voltage Vref of the regulator 20 is scarcely influenced by dispersions of the manufacturing process, the temperature, the power supply voltage, and so on. Hence, the output voltage Vrefpr (=Vref+Vth) of the regulator 20 is only influenced by any dispersion of the threshold voltage Vth of the transistor MN1. As described above, the threshold voltages Vth of the transistors MN1 and MN2 vary to approximately equal values. Since the pre-charge voltage of the bit line BL becomes a value obtained by eliminating the threshold voltage Vth of the transistor MN2 from the output voltage Vrefpr, influence of any dispersion of the threshold voltages Vth of the transistors MN1 and MN2 due to the process, the temperature, the power supply voltage, and so on, can be offset. As a result, the pre-charge voltage of the bit line BL can be set accurately to the reference voltage Vref that is scarcely influenced by any dispersion of the manufacturing process, the temperature, the power supply voltage, and so on.

### Second Embodiment

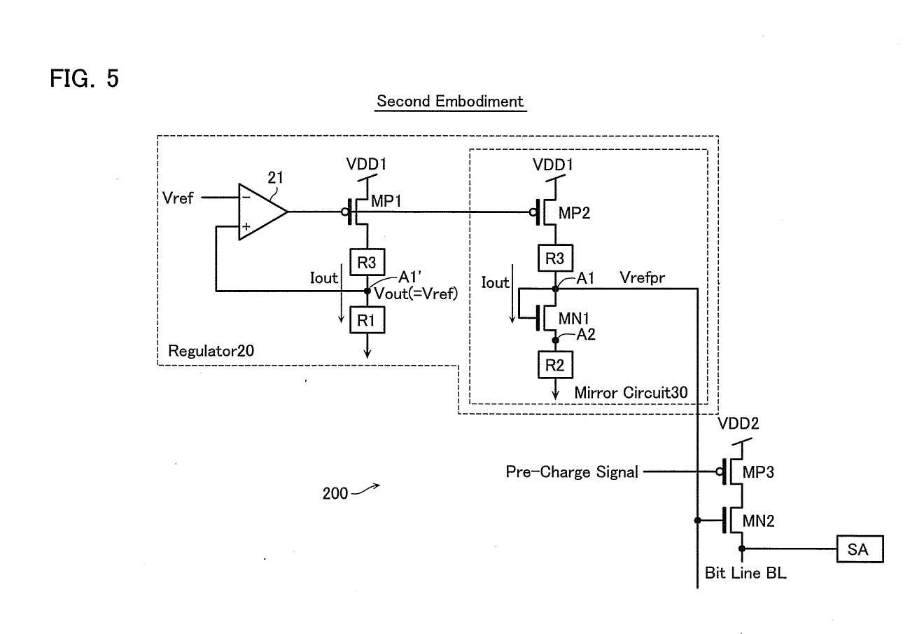

Next, a semiconductor memory device according to a second embodiment will be explained with reference to FIG. 5. In FIG. 5, any components that are configured the same as in the first embodiment will be denoted by the same reference numerals and redundant explanation about such components will not be given. A voltage generating circuit 200 according to the second embodiment is different from the first embodiment in that it includes a mirror circuit 30 configured to let flow therein a current having the same current value as a current Iout flowing through a node A1′ of the regulator 20.

The mirror circuit 30 according to the present embodiment includes a PMOS transistor MP2, resistors R2 and R3, and a transistor MN1. Like as described above, the transistor MN1 has an approximately equal characteristic to the transistor MN2, and the values of their threshold voltages Vth are also approximately equal. The resistor R3 in the mirror circuit 30 has the same resistance value as a resistor R3 provided between a transistor MP1 and the node A1′.

An output terminal of a differential amplifier 21 is connected to the gate of the transistor MP2. The transistor MP2 and the resistor R3 are connected in series between a power supply VDD1 and a node A1. The node A1 is grounded through the transistor MN1 and the resistor R2. The mirror circuit 30 is configured to equalize the value Iout of the current flowing through the node A1′ of the regulator 20 and the value Iout of the current flowing through the node A1. The mirror circuit 30 outputs an output voltage Vrefpr from the node A1. The value of the voltage Vrefpr of the node A1 is a sum (Iout×R2+Vth) of a product (Iout×R2) between the current Iout flowing through the node A1 and the resistance value of the resistor R2 and the threshold voltage Vth of the diode-connected transistor MN1. At this time, the voltage of a node A2 between the transistor MN1 and the resistor R2 becomes a product (Iout×R2) between the current Iout and the resistance value of the resistor R2. Here, by setting the resistance value of the resistor R2 to a value lower than the resistance value of the resistor R1 by Vth/Iout (i.e., R2=R1−Vth/Iout), it is possible to make the value of the output voltage Vrefpr approximately the same as the reference voltage Vref.

When pre-charging the bit line BL by using the voltage generating circuit 200 according to the present embodiment, the regulator 20 operates to equalize the voltage Vout of the node A1′ with the reference voltage Vref. At this time, the same current as the current Iout flowing through the node A1′ flows through the node A1 of the mirror circuit 30. The value of the output voltage Vrefpr of the node A1 of the mirror circuit 30 is Iout×R2+Vth as described above. The transistor MN2 connected to the bit line EL becomes conductive based on this output voltage Vrefpr (=Iout×R2+Vth). In this case, the bit line BL is clamped to a voltage (Iout×R2) lower than the output voltage Vrefpr (=Iout×R2+Vth) of the regulator 20 by the threshold voltage Vth of the transistor MN2.

[Advantage]

The reference voltage Vref of the regulator 20 and the resistor R2 of the mirror circuit 30 are scarcely influenced by dispersions of the manufacturing process, the temperature, the power supply voltage, and so on. Hence, the output voltage Vrefpr (=Iout×R2+Vth) of the regulator 20 is only influenced by any dispersion of the threshold voltage Vth of the transistor MN1. As described above, the threshold voltages Vth of the transistors MN1 and MN2 cause approximately equal dispersions. Since the pre-charge voltage of the bit line EL becomes a value obtained by eliminating the threshold voltage Vth of the transistor MN2 from the output voltage Vrefpr, influence of any dispersion of the threshold voltages Vth of the transistors MN1 and MN2 due to the process, the temperature, and the power supply voltage can be offset. As a result, it is possible to set the value of the pre-charge voltage of the bit line BL accurately to Iout×R2.

Here, when the voltage of the bit line greatly changes in the sensing operation, the output voltage Vrefpr is influenced by a coupling noise caused by a parasitic capacitance between the gate and source of the transistor MN2. If this noise is transmitted to the non-inverting input terminal of the differential amplifier 21 of the regulator 20, the output voltage Vrefpr might vary. As regards this problem, the voltage generating circuit 200 according to the present embodiment includes the mirror circuit 30 between the transistor MN2 (a clamp transistor) and the regulator 20. In this case, the noise can be transmitted to the mirror circuit 30, but is not to the differential amplifier 21. Hence, it is possible to set the pre-charge voltage of the bit line BL more accurately with no dispersion of the output voltage Vrefpr due to influence of the noise.

### Third Embodiment

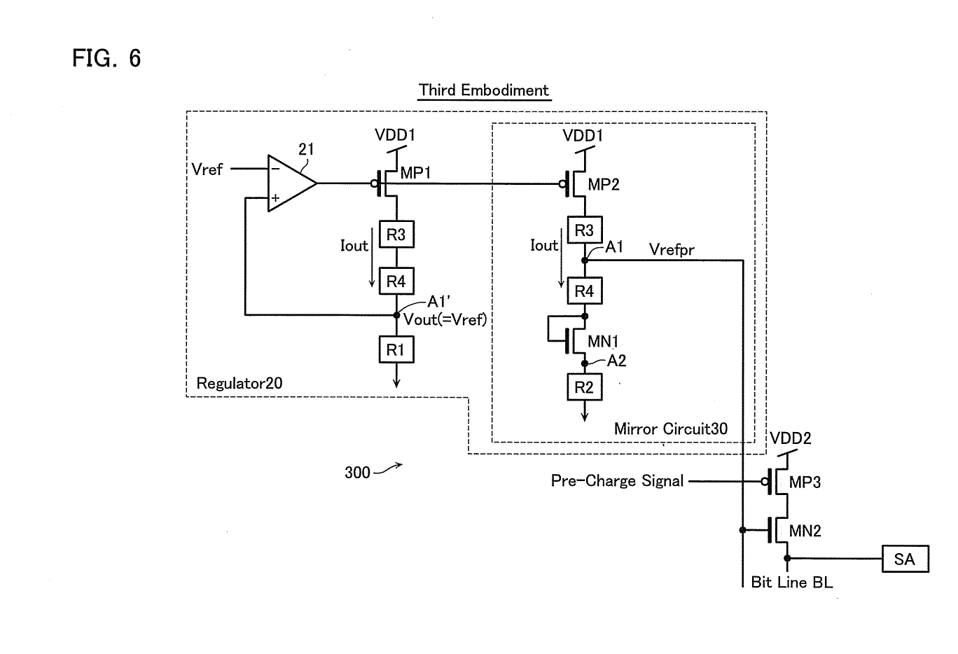

Next, a semiconductor memory device according to the third embodiment will be explained with reference to FIG. 6. In FIG. 6, any components that are configured the same as in the first and second embodiments will be denoted by the same reference numerals and redundant explanation about such components will not be given. A voltage generating circuit 300 according to the third embodiment is different from the second embodiment in that it includes resistors R4 in the regulator 20 and the mirror circuit 30 respectively.

The regulator 20 according to the present embodiment includes a resistor R4 between a resistor R3 and a node A1′ The mirror circuit 30 according to the present embodiment includes a resistor R4 between a node A1 and a transistor MN1. Here, the resistors R4 in the regulator 20 and the mirror circuit 30 are configured to have the same resistance value.

Also the mirror circuit 30 according to the present embodiment outputs an output voltage Vrefpr from the node A1. The value of the voltage Vrefpr of the node A1 is a sum (Iout×(R2+R4)+Vth) of a product (Iout×(R2+R4)) between a current Iout flowing through the node A1 and the resistance values of the resistors R2 and R4 and a threshold voltage Vth of the diode-connected transistor MN1. In this case, the voltage of a node A2 between the transistor MN1 and the resistor R2 becomes a product (Iout×R2) between the current Iout and the resistance value of the resistor R2. Here, if the resistance value of the resistor R2 is set to a value smaller than the resistance value of the resistor R1 by Vth/Iout (i.e., R2=R1−Vth/Iout), the value of the output voltage Vrefpr becomes a value higher than the reference voltage Vref by Iout×R4.

When pre-charging the bit line BL by using the voltage generating circuit 300 according to the present embodiment, the regulator 20 operates to equalize the voltage Vout of the node A1′ with the reference voltage Vref. At this time, the same current as the current Iout flowing through the node A1′ flows through the node A1 of the mirror circuit 30. As described above, the value of the output voltage Vrefpr of the node A1 of the mirror circuit 30 is Iout×(R2+R4)+Vth. The transistor MN2 connected to the bit line BL becomes conductive based on this output voltage Vrefpr (=Iout×(R2+R4)+Vth). In this case, the bit line BL is clamped to a voltage (Iout×(R2+R4)) lower than the output voltage Vrefpr (=Iout×(R2+R4)+Vth) of the regulator 20 by the threshold voltage Vth of the transistor MN2.

[Advantage]

Like in the embodiments described above, the pre-charge voltage of the bit line BL becomes a value obtained by eliminating the threshold voltage Vth of the transistor MN2 from the output voltage Vrefpr. Therefore, influence of any dispersion of the threshold voltages Vth of the transistors MN1 and MN2 due to the process, the temperature, and the power supply voltage can be offset. Hence, it is possible to set the pre-charge voltage of the bit line BL accurately. Furthermore, since also the voltage generating circuit 300 according to the present embodiment includes the mirror circuit 30, the output voltage Vrefpr will not vary due to influence of a noise, allowing the pre-charge voltage of the bit line EL to be set more accurately. The mirror circuit 30 according to the present embodiment includes the resistor R4 between the node A1 and the transistor MN1. This enables the value of the output voltage Vrefpr to become higher than the reference voltage Vref, allowing the pre-charge voltage of the bit line BL to be set higher.

### Fourth Embodiment

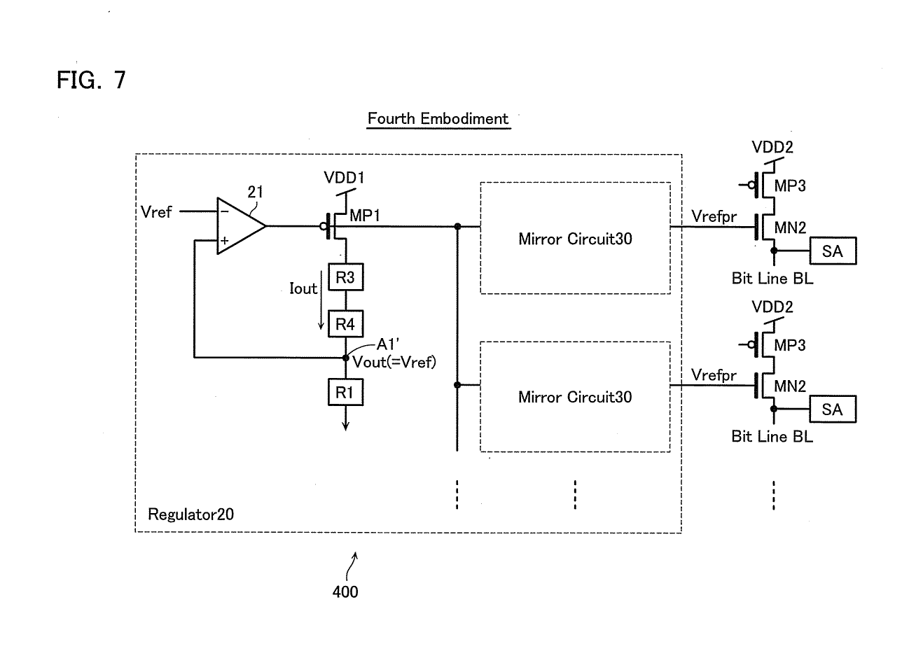

Next, a semiconductor memory device according to a fourth embodiment will be explained with reference to FIG. 7. In FIG. 7, any components that are configured the same as in the other embodiments will be denoted by the same reference numerals and redundant explanation about such components will not be given. A voltage generating circuit 400 according to the fourth embodiment is different from the second and third embodiments in that it includes a plurality of mirror circuits 30.

The configuration of the mirror circuits 30 according to the present embodiment may be as either of the second and third embodiments. The plurality of mirror circuits 30 are each connected to an output terminal of a differential amplifier 21. Being provided with a plurality of mirror circuits 30, the regulator 20 can output an output voltage Vrefpr to a plurality of transistors MN2 (clamp transistors). For example, such a number of mirror circuits 30 as equal to the number of blocks are provided, and hence different blocks are supplied with the output voltage Vrefpr from different mirror circuits 30. A plurality of clamp transistors MN2 provided for each bit line in one block are supplied with the output voltage Vrefpr from one mirror circuit 30.

[Advantage]

Like in the embodiments described above, the pre-charge voltage of the bit line BL becomes a value obtained by eliminating the threshold voltage Vth of the transistor MN2 from the output voltage Vrefpr. Therefore, influence of any dispersion of the threshold voltages Vth of the transistors MN1 and MN2 due to the process, the temperature, and the power supply voltage can be offset. Hence, it is possible to set the pre-charge voltage of the bit line BL accurately. Furthermore, since the voltage generating circuit 400 according to the present embodiment includes a plurality of mirror circuits 30, it is possible to supply pre-charge voltages having approximately equal values to the plurality of bit lines BL constituting one block. The use of the voltage generating circuit 400 according to the present embodiment enables block-by-block adjustment of the values of the pre-charge voltages of the bit lines BL, allowing the pre-charge voltages of the bit lines BL to be set more effectively to offset any dispersion of characteristics in the memory cell array.

[Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

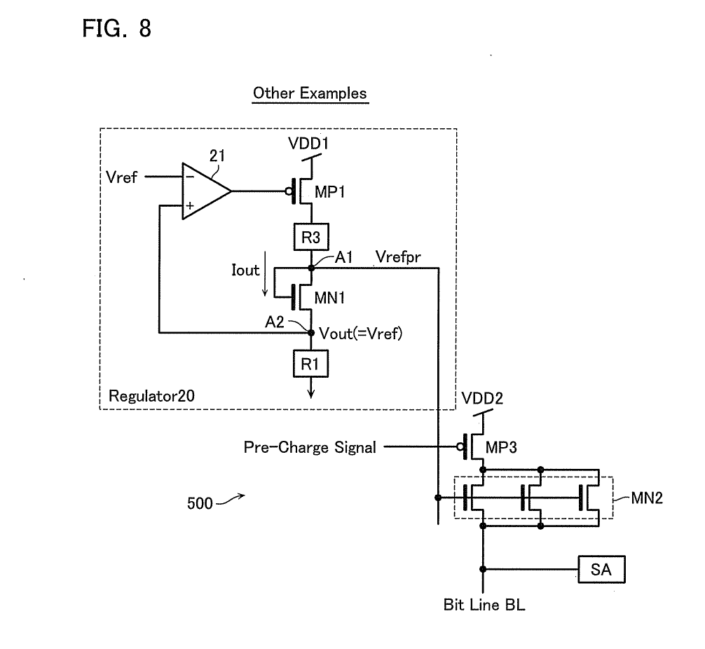

For example, the above embodiments have explained that the transistor MN1 provided in the voltage generating circuit and the transistor MN2 to function as the clamp transistor have approximately equal characteristics. However, the transistors MN1 and MN2 need not be single transistors having equal characteristics, but they only need to be in a certain relationship that enables them to offset influence of any dispersion of their threshold voltages Vth. For example, the transistor MN2 may be a transistor having a size that is an integer multiple of the size of the transistor MN1. FIG. 8 is a circuit diagram showing a voltage generating circuit 500 of a semiconductor memory device according to another example. As shown in FIG. 8, a transistor MN2 having a size that is an integer multiple of the size of the transistor MN1 can be formed by connecting in parallel a plurality of transistors each having the same gate length and gate width as those of the transistor MN1.

Furthermore, in the mirror circuit 30 according to the second and third embodiments, by locating the elements provided between the node A1 and the grounding terminal (i.e., the transistor MN1 and the resistor R2 in FIG. 5, and the transistor MN1 and the resistors R2 and R4 in FIG. 6) such that they become close to the memory cell array, it is possible to provide more approximately equal characteristics to the transistor MN1 and the transistor MN2. This enables influence of any dispersion of the threshold voltages Vth to be offset more effectively during the operation of pre-charging the bit line BL. Though the explanation has been given by employing a memory cell array of a NAND type flash memory as an example of a semiconductor memory device, needless to say, the embodiments of the present invention can be applied to any semiconductor memory device as long as it involves charging of bit lines when performing operations.

What is claimed is:

1. A semiconductor memory device, comprising:
a memory cell array including electrically-rewritable memory cells;
bit lines each connected to one end of the memory cells and charged in response to a certain operation; and
a voltage generating circuit configured to control a charging operation on the bit lines,
the voltage generating circuit including: a regulator configured to regulate voltages of a first node and a second node; and a clamp transistor connected at its one end to a bit line and connected at its gate to the first node,
the regulator including a first transistor diode-connected between the first node and the second node to form a current path therebetween and configured to let flow therethrough an output current variable according to an output signal of the regulator, and
the first transistor and the clamp transistor having approximately equal threshold voltages.

2. The semiconductor memory device according to claim 1,
wherein the regulator further includes a first resistor element connected between the second node and a grounding terminal, and
the first resistor element generates a certain voltage at the second node by letting flow therethrough the output current that flows through the first transistor.

3. The semiconductor memory device according to claim 2,
wherein the regulator further includes a differential amplifier configured to differentially amplify a reference voltage and the voltage of the second node to vary the output signal.

4. The semiconductor memory device according to claim 3,
wherein the regulator further includes:
a second transistor supplied at its gate with the output signal of the differential amplifier; and
a second resistor element connected between the second transistor and the first node.

5. The semiconductor memory device according to claim 1,
wherein the regulator further includes:
a differential amplifier configured to differentially amplify a reference voltage and a voltage of a third node to vary the output signal; and
a mirror circuit configured to mirror the output current generated based on the output signal and let flow the output current to the first node, the first transistor, and the second node.

6. The semiconductor memory device according to claim 5,
wherein the mirror circuit is configured to generate the same voltages at the second node and the third node.

7. The semiconductor memory device according to claim 5,
wherein the regulator further includes a plurality of mirror circuits.

8. A semiconductor memory device, comprising:
a memory cell array including electrically-rewritable memory cells;
bit lines each connected to one end of the memory cells and charged in response to a certain operation; and
a voltage generating circuit configured to control a charging operation on the bit lines,
the voltage generating circuit including: a regulator configured to regulate voltages of a first node and a second node; and a clamp transistor connected at its one end to a bit line and connected at its gate to the first node,
the regulator including a first transistor diode-connected between the first node and the second node to form a current path therebetween and configured to let flow therethrough an output current variable according to an output signal of the regulator, and
a threshold voltage of the first transistor having a certain relationship with a threshold voltage of the clamp transistor.

9. The semiconductor memory device according to claim 8,
wherein the clamp transistor has a size that is an integer multiple of the size of the first transistor.

10. The semiconductor memory device according to claim 8,
wherein the regulator further includes a first resistor element connected between the second node and a grounding terminal, and
the first resistor element generates a certain voltage at the second node by letting flow therethrough the output current that flows through the first transistor.

11. The semiconductor memory device according to claim 10,
wherein the regulator further includes a differential amplifier configured to differentially amplify a reference voltage and the voltage of the second node to vary the output signal.

12. The semiconductor memory device according to claim 11,
wherein the regulator further includes:
a second transistor supplied at its gate with the output signal of the differential amplifier; and
a second resistor element connected between the second transistor and the first node.

13. The semiconductor memory device according to claim 8,
wherein the regulator further includes:
a differential amplifier configured to differentially amplify a reference voltage and a voltage of a third node to vary the output signal; and
a mirror circuit configured to mirror the output current generated based on the output signal and let flow the output current to the first node, the first transistor, and the second node.

14. The semiconductor memory device according to claim 13,
wherein the mirror circuit is configured to generate the same voltages at the second node and the third node.

15. A semiconductor memory device, comprising:
a memory cell array including: memory strings each having electrically-rewritable memory cells connected in series; first select transistors connected to one end of the memory strings respectively; second select transistors connected to the other end of the memory strings respectively; bit lines each connected to one of the memory strings via a first select transistor; a source line connected to the memory strings via the second select transistors; and word lines each connected to a control gate electrode of the memory cells; and
a voltage generating circuit configured to control a charging operation on the bit lines in response to a certain operation,
the voltage generating circuit including: a regulator configured to regulate voltages of a first node and a second node; and a clamp transistor connected at its one end to a bit line and connected at its gate to the first node,
the regulator including a first transistor diode-connected between the first node and the second node to form a current path therebetween and configured to let flow therethrough an output current variable according to an output signal of the regulator, and
the first transistor and the clamp transistor having approximately equal threshold voltages.

16. The semiconductor memory device according to claim 15,
wherein the regulator further includes a first resistor element connected between the second node and a grounding terminal, and
the first resistor element generates a certain voltage at the second node by letting flow therethrough the output current that flows through the first transistor.

17. The semiconductor memory device according to claim 16,
wherein the regulator further includes a differential amplifier configured to differentially amplify a reference voltage and the voltage of the second node to vary the output signal.

18. The semiconductor memory device according to claim 17,
wherein the regulator further includes:
a second transistor supplied at its gate with the output signal of the differential amplifier; and
a second resistor element connected between the second transistor and the first node.

19. The semiconductor memory device according to claim 15,
wherein the regulator further includes:
a differential amplifier configured to differentially amplify a reference voltage and a voltage of a third node to vary the output signal; and
a mirror circuit configured to mirror the output current generated based on the output signal and let flow the output current to the first node, the first transistor, and the second node.

20. The semiconductor memory device according to claim 19,
wherein the mirror circuit is configured to generate the same voltages at the second node and the third node.
